(19) United States
(12) Patent Application Publication
(10) Pub. No.: US 2002/0153578 A1
(43) Pub. Date: Oct. 24, 2002

(54) Wafer buffering system

(76) Inventors: Ravinder Aggarwal, Gilbert, AZ (US); Ivo Raaijmakers, Bilthoven (NL)

Correspondence Address: KNOBBE MARTENS OLSON & BEAR LLP, 2040 MAIN STREET, FOURTEENTH FLOOR, IRVINE, CA, 91614, US

(21) Appl. No.: 10/090,414

(22) Filed: Feb. 28, 2002

Related U.S. Application Data
(60) Provisional application No. 60/272,638, filed on Mar. 1, 2001.

(51) Int. Cl. H01L 29/76

(52) U.S. Cl. 257/400

(57) ABSTRACT

Wafer buffering systems for use with a wafer processing system include a frame and wheel. The wheel includes a plurality of shelves for supporting a plurality of wafer carriers. The wheel is supported by the frame for rotation about a generally horizontal axis. The plane of the wheel faces a semiconductor processing system (e.g., a cluster tool) with an intervening wafer transfer robot located preferably between the wheel and the semiconductor processing system. A cassette transfer system moves cassettes from the wheel to a port for interfacing with the wafer transfer robot. In another arrangement, a horizontal carousel stocks cassettes above the processing system.

### PRIORITY INFORMATION

This application claims the priority benefit under 35 U.S.C. § 119(e) of Provisional Application No. 60/272,638 filed Mar. 1, 2001.

### FIELD OF THE INVENTION

The present invention relates generally to equipment for handling and processing semiconductor wafers and, in particular, to wafer buffering systems for use with a wafer processing system.

### BACKGROUND OF THE INVENTION

In the processing of integrated circuits, a plurality of devices are fabricated simultaneously on a semiconductor substrate, such as a silicon wafer. The wafers are fabricated within a wafer processing system, which typically includes one or more processing modules and a wafer handling assembly for transferring the wafers between the one or more processing modules. Each module can, for example, deposit, pattern etch, dope, anneal or oxidize, layers that eventually define a completed integrated circuit.

“Lot buffering” is a method for improving the throughput of wafers through the wafer processing system. Lot buffering typically involves stocking each wafer processing system with a large supply of wafers, generally at the same stage of fabrication. Typically, these wafers are stored in cassettes, which can be open or enclosed. The cassettes, in turn, are stored within a wafer buffering system that typically includes a transfer mechanism for moving the cassettes within the buffering system. The buffering system typically also includes a cassette transfer mechanism for transferring cassettes and/or a wafer transfer mechanism for transferring wafers from the buffering system to the processing system, and an input/output station port for the passage of cassettes between the buffering system and the outside clean room generally. This arrangement provides the wafer processing system with a constant supply of wafers and ensures that the wafer processing system is never left idling.

There are, however, several disadvantages associated with prior art wafer buffering systems. For example, most prior art wafer buffering systems take up a significant amount of floor space. Thus, addition of a wafer buffering system typically increases the footprint of a wafer processing station. Moreover, the transfer mechanisms of prior art buffering system are typically quite complex and expensive.

### SUMMARY OF THE INVENTION

Accordingly, one aspect of the present invention involves a buffering system for use with a wafer processing system. The buffering system includes a frame and a wheel supported within the frame for rotation about a generally horizontal axis. The wheel supports a plurality of wafer carriers.

In the illustrated embodiments, a shuttle system is provided for unloading wafer carriers (e.g., cassettes) from shelves on the wheel to a support. The shuttle can then transfer cassettes to a cassette port at the center of the wheel. There, a robot on the other side of the cassette port can access wafers within the carrier.

Another aspect of the present invention involves a buffering system for use with a wafer processing system. The buffering system includes a frame and a wheel that supported therein for rotation about a generally vertical axis. The wheel is so supported above the wafer processing system. The wheel includes a plurality of positions for supporting a plurality of wafer carriers.

These aspects are intended to be within the scope of the invention herein disclosed. These and other aspects of the present invention will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

FIG. 1 is a schematic top plan view of a processing station that includes a processing system and a buffering system having certain features and advantages according to a first embodiment of the present invention;

FIG. 2 is schematic front elevation view of the buffering system of FIG. 1;

FIG. 3 is a schematic top plan view of a modified arrangement of a processing station that includes a wafer processing system and a buffering system having certain features and advantages according to a second embodiment of the present invention;

FIG. 4 is a schematic top plan view of another modified arrangement of a processing station that includes a wafer processing system and a buffering system having certain features and advantages according to a third embodiment of the present invention;

FIG. 5 is a schematic, cross-sectional side view of the processing station, taken along lines 5-5 of FIG. 4;

FIG. 6 is a schematic top plan view of a yet another modified arrangement of a processing station that includes a wafer processing system and a buffering system having certain features and advantages according to a fourth embodiment of the present invention;

FIG. 7 is a schematic, cross-sectional side view of the processing station, taken along lines 7-7 of FIG. 6;

FIGS. 8A-C are schematic top, side and front views, respectively, of still another modified arrangement of a processing station that includes a wafer processing system and a buffering system having certain features and advantages according to a fifth embodiment of the present invention; and

FIGS. 9A-C are schematic top, side and front views, respectively, of another modified arrangement of a processing station that includes a wafer processing system and a buffering system having certain features and advantages according to a sixth embodiment of the present invention.

### DETAILED DESCRIPTION OF THE PREFERRED EMBODIMENT

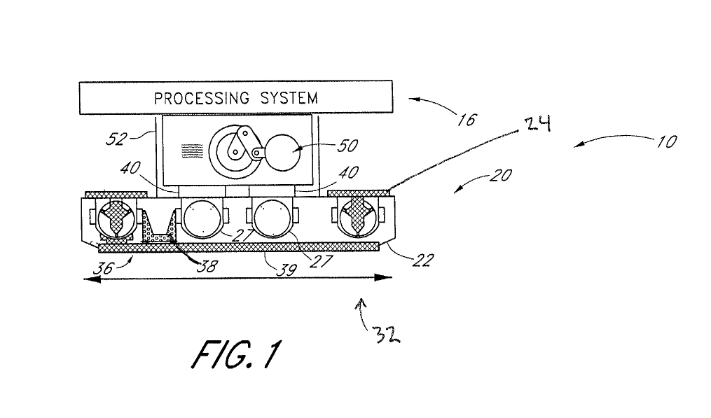

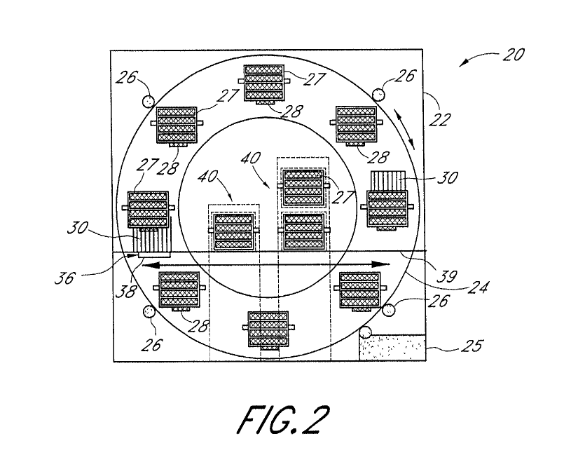

FIGS. 1 and 2 illustrate a wafer processing station 10 that includes a processing system 16 for processing wafers and a buffering system 20 having certain features and advantages according to a first preferred embodiment of the present invention. The illustrated buffering system 20 comprises a frame 22 and a wheel 24 that is suitably supported by the frame for rotation about a generally horizontal axis within or adjacent the frame 22 by a plurality of bearings 26. A drive mechanism 25 (shown schematically only) is provided for rotating the wheel 24 within or adjacent the frame 22.

The wheel 24 supports a plurality of shelves 28. In the illustrated arrangement, each shelf 28 is configured to support a wafer carrier 27, in which several wafers are preferably stacked in a cassette-type structure. In the illustrated arrangement, the wafer carrier 27 is a standard front opening unified pod (“FOUP”), which includes a door and forms a closed environment for the wafers. The construction of the FOUP is established by Semiconductor Equipment Materials International (SEMI) standards, which are herein incorporated by reference. In other arrangements, it will be understood that the buffer frame 22 can define a closed environment and “open” cassettes can be used.

In the illustrated arrangement, the wheel 24 includes eight (8) shelves; however, it should be appreciated that the wheel can include greater or fewer shelves giving due consideration to the size of the wheel and the desired capacity of the buffering system. Each shelf 28 preferably is configured to rotate in a manner to keep the cassettes 27 level as the wheel 24 rotates. In a modified arrangement, the cassettes and shelves can be modified such that the cassettes hang from the shelves or are directly and pivotally hung from the wheel.

The buffering system 20 preferably includes at least one input/output station (“I/O station”) 30, which is configured to allow transport of a wafer carrier 27 therethrough. The illustrated buffering system 20 includes two I/O stations 30, which are located on a front side 32 (i.e., opposite the wheel 24) of the buffering system 20. However, it should be appreciated that in modified arrangements the I/O stations 30 can be located at the bottom, the front, the top and/or either side of the buffering system 20. For example, if an overhead hoist transport (“OHT”) is used to deliver the wafer carriers to and from the buffering system, the I/O stations are preferably located on top of the buffering system or on an upper portion of the buffering system.

The I/O stations 30 are preferably configured such that a wafer carrier 27 can be loaded directly onto a shuttle, which is indicated generally by the reference number 36. While shown with one, it will be understood that a second shuttle can be provided such that each I/O station has a dedicated shuttle. The illustrated shuttle 36 comprises a support 38 for supporting a wafer carrier 27, a track 39 on which the support 38 can be moved back and forth within the buffering system 20 and a drive mechanism (not shown) for moving the support 38 back and forth within the buffering system 20. The shuttle 36 is configured to move the wafer carriers 27 within the buffering system 20. More specifically, in the illustrated arrangement, the shuttle 36 is configured to receive a wafer carrier 27 directly from an I/O station 30. From the I/O station 30, the shuttle 36 can (i) position a wafer carrier 27 on one of the shelves 28 and/or (ii) position a wafer carrier 27 in front of a wafer carrier port 40, which will be described below. The shuttle 36 preferably can also move a wafer carrier 27 from the wafer carrier port 40 to one of the shelves 28 and/or an I/O station 30. Preferably, wafer carriers 27 are transferred from the shelves 28 to the support 38, by positioning the support 38 under the shelves 28 in a manner that interferes with the rotation (counter-clockwise in the view of FIG. 2) of the wafer carrier 27 on the wheel 24. In a similar manner, wafer carriers 27 are preferably transferred to the shelves 28 from the support 38, by positioning the support 38 with a wafer carrier above a shelf 28 so as to interfere with the rotation (clockwise in the view of FIG. 2) of the shelf 28 on the wheel 24.

In modified arrangement, the I/O stations 30 can be configured such that a wafer carrier 27 can be loaded directly onto one of the shelves 28. In such an arrangement, the shuttle 36 can be arranged to move wafer carriers 27 from the shelves 28 to the wafer carrier port 40 and from the wafer carrier port 40 to the shelves 28. In another modified arrangement, the shuttle 36 can be configured to remove a shelf 28 from the wheel 24. In such an arrangement, the shuttle 36 can use the shelf 28 to support a wafer carrier 27 as the wafer carrier 27 is moved within the wafer buffering system 20.

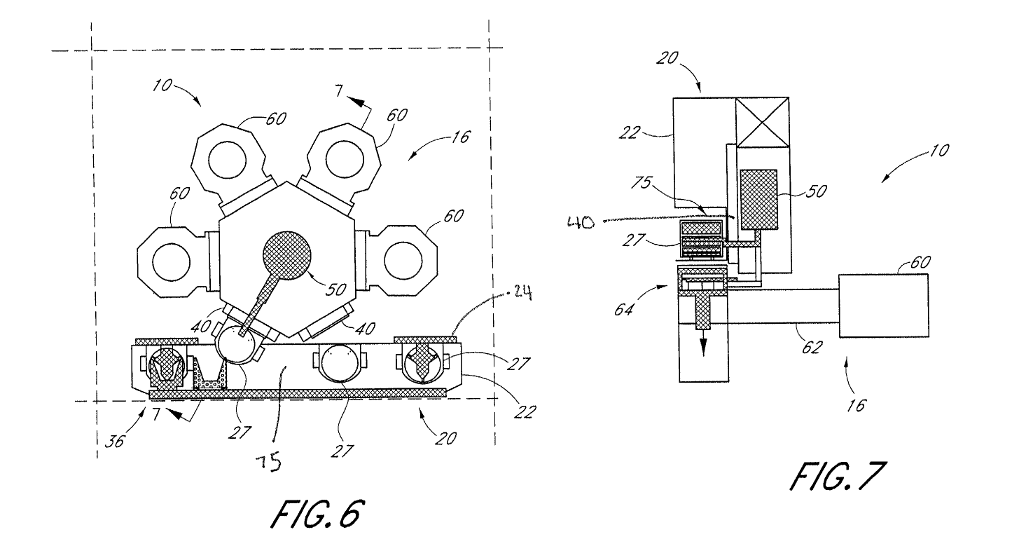

As mentioned above, the wafer buffering system 20 includes at least one wafer carrier port 40. In the illustrated arrangement, the wafer buffering system includes three (3) wafer carrier ports 40. Moreover, in the illustrated arrangement, two of the wafer carrier ports 40 are stacked on top of each other. Accordingly, the wafer illustrated buffering system 20 is preferably provided with another shuttle (not shown) that is configured to move wafer carriers 27 between an upper I/O port 30 and/or shelf 28 and the wafer carrier port 40 that is not accessible by the first shuttle 36. In a modified arrangement, the shuttle 36 can include an elevator mechanism to facilitate wafer carrier 27 drop off at the carrier ports 40 above or below the shuttle 36 and/or the carrier ports 40 at the level of the shuttle 36. The shuttle 36 can also include the ability for lateral and/or pivoting movement to facilitate the engagement between a wafer carrier 27 and a wafer carrier port 40 (see FIG. 6 and accompanying text). It should also be appreciated that the wafer buffering system 20 can be modified to include more wafer carrier ports 40 and/or I/O stations 30 arranged differently depending upon the size and shape of the buffering system 20. For example, the wafer buffering system can include two pairs of stacked carrier ports serviced by two shuttles at different vertical levels. In yet another arrangement, the wafer buffering system can include three carrier ports that are all located in the same horizontal plane and serviced by a single shuttle.

As mentioned above, the wafer carriers 27 of the illustrated arrangement are standard front opening unified pods (“FOUPs”). As such, the wafer carrier ports 40 are preferably configured in accordance with SEMI standard E 62-0997, which are provisional specifications for 300-mm Front Opening Interface Mechanical Standards and are incorporated herein by reference. Moreover, the stacked carrier ports 40 preferably are configured as described in U.S. patent application No. 6,042,323, which is also incorporated herein by reference. Accordingly, in the illustrated arrangement, the shuttle 36 positions the wafer carrier 27 in front of the wafer carrier ports 40. After the wafer carrier 27 is in position, the wafer carrier ports 40 open the doors of the wafer carriers 27 such that the wafers within the wafer carrier 27 can be removed through the carrier ports 40 by a wafer handling robot 50.

Preferably, as shown in FIG. 1, the wafer handling robot 50 is provided between the wafer buffering system 20 and a processing system 16. As mentioned above, the wafer handling robot 50 is configured to remove a wafer from the wafer carrier 27 through the wafer carrier port 40. Once removed, the atmospheric robot 50 can transfer the wafer to the processing system 16. This might involve, for example, placing the wafer within a load lock (not shown) of the wafer processing system 16. The processing system 16 can comprise a single processing chamber but more preferably comprises a cluster tool with multiple process modules therein. After the wafer is processed, the wafer handling robot 50 removes the wafer from the processing system 16 and places the wafer within the wafer carrier 27.

Preferably, a wall 52 surrounds the wafer handling robot 50 so as to create a mini-environment between the wafer carrier 27 and the processing system 16. In this manner, a wafer can be transported between the processing system 16 and the wafer carrier 27 in a substantially particle free environment.

The arrangement described above have several advantages. For example, the illustrated buffering system 20 provides random access to the wafers of eight wafer carriers 27. In addition, random access can be provided to greater or fewer than eight wafer by adjusting the size of the wheel 24 and/or the number of shelves 28. The illustrated buffering system 20 also has a depth selected to accommodate a single wafer carrier 27 and container port 40. Prior art buffering systems typically include an expensive, complex robot for moving the wafer carriers 27. In contrast, the illustrated arrangement utilizes linear motion of the shuttle 36 and the rotation of the wheel 24 to provide random access to the wafers in the wafer carriers 27. This buffering system 20 also can be easily modified to fit most processing systems.

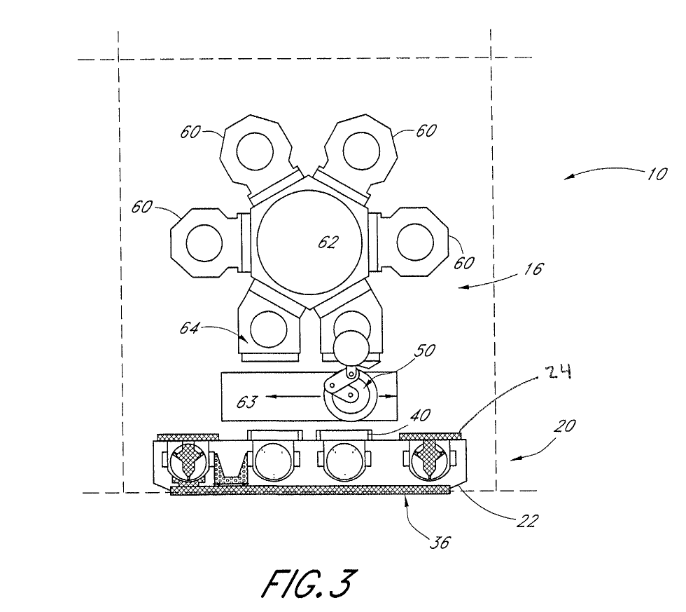

FIG. 3 illustrates a second embodiment of the present invention. The main difference between this embodiment and the previous embodiment is the interface between the wafer buffering system 20 and the processing system 16. The illustrated processing system 16 is a cluster-type processing system, which includes a plurality (four shown) of processing modules 60, a wafer handling chamber 62 and two wafer inlet/outlet stations or load lock chambers 64. The atmospheric robot 50 (i.e., wafer handling robot outside the cluster tool 16, for interfacing with the buffering system 20) preferably is located on a linear track 63 such that the robot 50 can move wafers between two load lock chambers 64 and the wafer carrier ports 40.

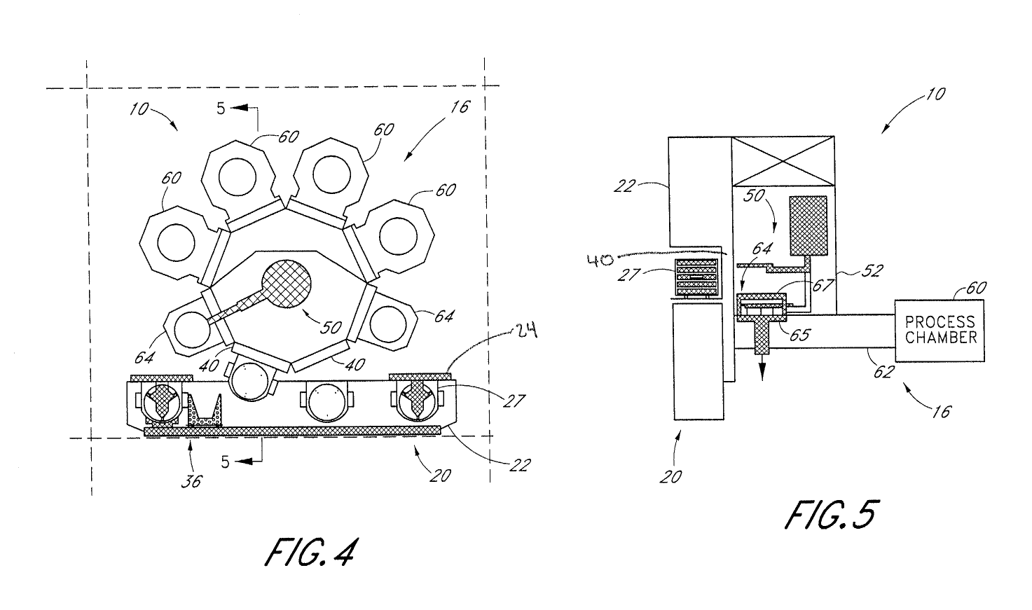

FIGS. 4 and 5 illustrate a third embodiment of the present invention. In this arrangement, the buffering system 20 is preferably configured as described above. However, in this arrangement, the wafer handling robot 50 is located above the wafer handling chamber 62 of the processing system 16. Moreover, the wafer handling chamber 62 preferably includes one or more vertical load locks 64.

In the illustrated arrangement, the vertical load locks 64 are configured to move vertically between a upper position, which is illustrated in FIG. 5, and a lower position. In the upper position, the interior of the load lock 64 is accessible to the wafer handling robot 50 so that one or more wafers can be removed from a cassette through the wafer carrier port 40 and placed into the load lock 64. The load lock 64 preferably includes a lower plate 65, which seals against upper wall of the wafer handling chamber 62 to isolate the wafer handling chamber 62 when the load lock 64 is in the upper position. In the lower position, the interior of the load lock 64 is accessible to a second wafer handler (not shown) in the wafer handling chamber 62. The load lock 64 preferably includes an upper plate 67 that seals against the wafer handling chamber 62 to isolate the wafer handling chamber 62 when the load lock 64 is in the lower position.

In the illustrated arrangement, the wafer carrier ports 40 are located at an angle with respect to the buffering system 20. This arrangement makes the wafer carrier ports 40 more accessible to the wafer handling robot 50. As such, in the illustrated arrangement, the shuttle 36 is preferably configured to pivot and possibly move the wafer carriers forward into position in front of the wafer carrier ports 40. Of course, in a modified arrangement, the wafer carrier ports 40 can be configured more perpendicular to the wafer buffering system 20, as in the arrangements described above.

As compared to the previous embodiment, this embodiment is more compact and thus takes up less floor space because the wafer handling robot 50 and lock chambers 64 occupy the same footprint as the wafer handling chamber 62.

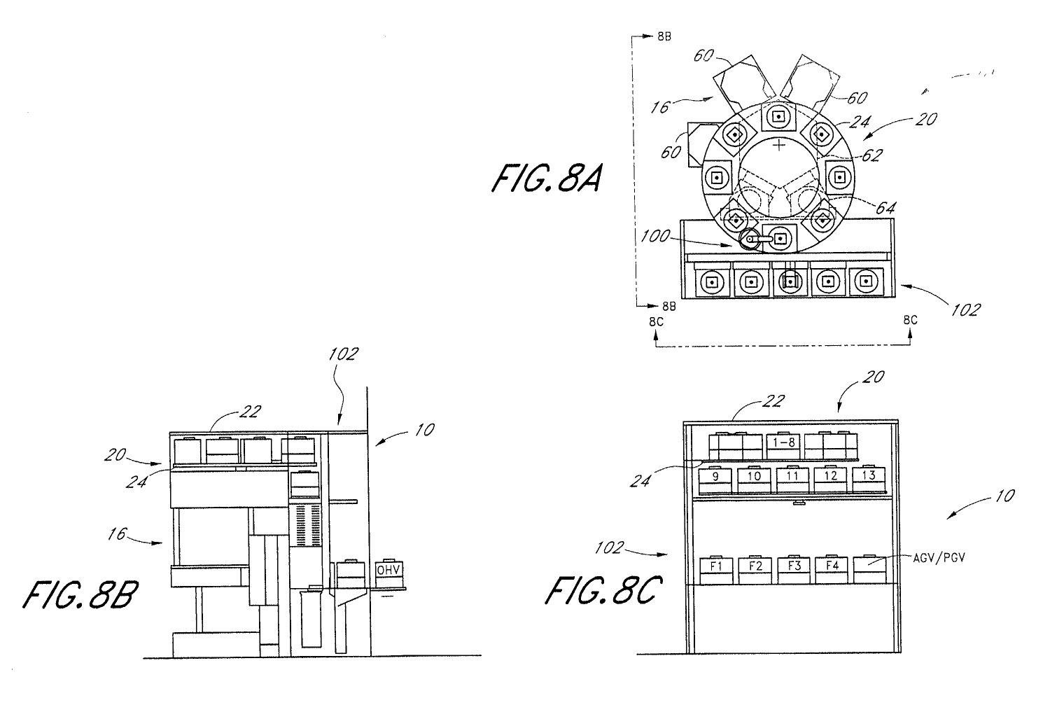

FIGS. 6 and 7 illustrates a fourth embodiment of the present invention. In this arrangement, the wafer buffering system 20 preferably is configured as described above. The wafer handling robot 50 is located above the wafer handing chamber 62 as in the third embodiment. However, in this embodiment, the vertical load locks 64 are located substantially under the wafer carrier 27 when it is engaged with the wafer carrier port 40. That is, at least a portion of the load lock 64 and the wafer handling chamber 62 extend into the wafer buffering system 20, preferably, in a space 75 located generally at the center of the wheel 24 (see also FIG. 1). As with the third embodiment, the wafer carrier ports 40 are located at an angle to the wafer buffering system 20 and the shuttle 36 preferably is configured to pivot and possibly move the wafer carriers 27 forward into position in front of the wafer carrier ports 40. Of course, the position of the wafer carrier port 40 can be modified as described above. As compared to the third embodiment, this arrangement further reduces the amount of floor space occupied by the buffering system 20 and processing system 16.

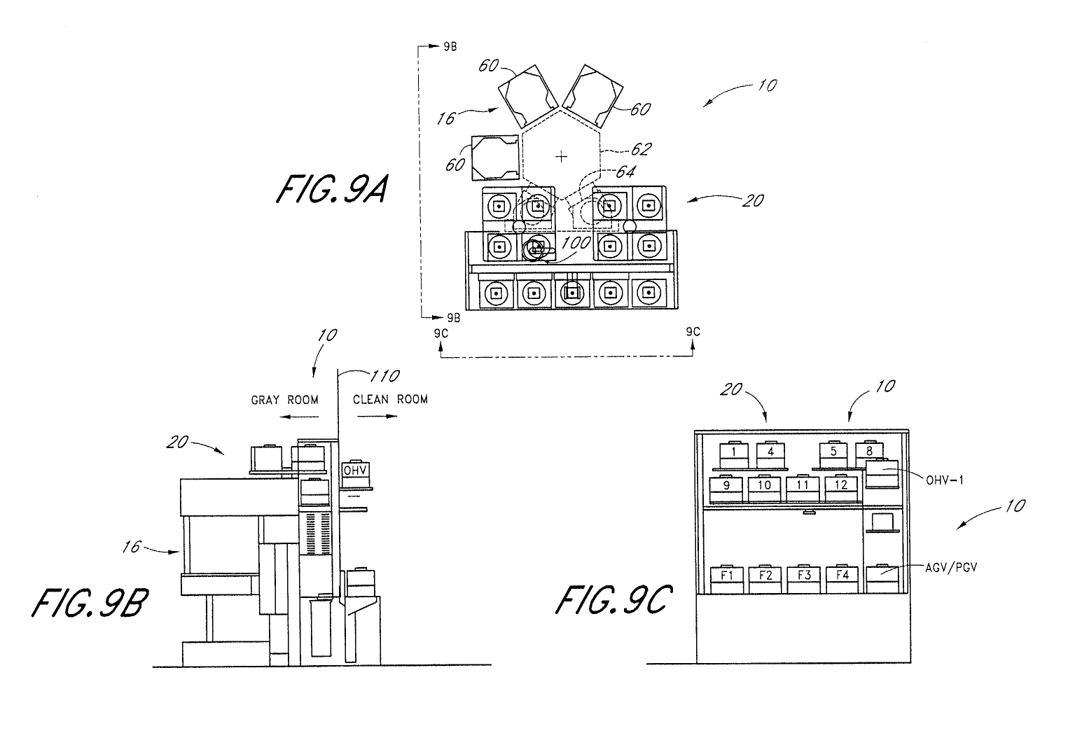

FIGS. 8A-C illustrate a fifth embodiment of the present invention. In this arrangement of the processing tool or station 10, the buffering system 20 is located in the space above the processing system 16. More specifically, in the illustrated arrangement, the processing system 16 is a cluster type processing system and the buffering system 20 is largely located above the wafer handling chamber 62 and process chambers 60.

The illustrated buffering system 20 comprises at least one and preferably a plurality of wheels or carousels 24, in which wafer carriers 27 are stored. As with the previous arrangements, the wheels 24 are configured to rotate within the buffering system 20 and preferably supported by a frame 22; however in this arrangement the wheels 24 rotate in the horizontal dimension about a generally vertically extending axis, such that they operate as carousels. To expand the capacity of the buffering system 20, additional wheels can be added on top of the illustrated wheel 24. Of course, the buffering system 20 can be formed with only one wheel 24 if desired.

A buffer cassette transfer robot 100, preferably a gantry type robot which moves only in a singular Cartesian direction at one time (x, y or z), is provided in the buffering system 20 for transferring the wafer carriers 27 to the wafer processing system 16 below. In a modified arrangement, the buffer cassette transfer robot 100 can be configured for rotational movement.

Once inside the processing system, the door of the wafer carrier 27 can be opened (for a FOUP-type wafer carrier 27) and the wafers can be transferred to the processing modules 60 by a second robot within the wafer handling chamber 62 shown in dotted lines beneath the buffer system on the cluster tool level. In a modified arrangement, the door of the wafer carriers 27 can be opened in the buffering system and a robot can remove individual wafers from the wafer carriers 27 and transfer the wafers to the processing system 16.

The arrangement preferably also includes a front end stocker 102, which, in the illustrated arrangement, is located in front of the processing system 16. The front end stocker 102 comprises a series of shelves that can be used to store additional wafer carriers 27. Preferably, the buffer cassette transfer robot 100 can also access the wafer carriers 27 stored in the front end stocker 102 and transfer wafer carriers 27 between the front end stocker 102 and the wafer buffering system 20. The stocker 102 can serve as an I/O station, directly communicating with an overhead hoist and/or automatically guided vehicle (AGV), as shown.

The arrangement described above has several advantages. For example, because the buffering system lies above the processing system, the overall footprint of the processing station 10 is not increased. The buffering system 20 also provides random access to the wafer carriers 27 and provides a modular structure that can be expanded by adding additional wheels 24.

FIGS. 9A-9C illustrate a sixth embodiment of the present invention. As with the arrangement of FIGS. 8A-8C, the buffering system 20 is located above the wafer processing system 16. However, in this arrangement, the wafer carriers 27 are located in a rectangular fixed station 20. Preferably, a cassette transfer robot 100 is provided for moving the wafer carriers within the buffering system 20. A wall 110 (FIG. 9B) is also shown, separating the buffering system 20 and processing system 16 from the clean room environment.

In the arrangements described above, the wafer carrier 27 is a FOUP, which commonly used and is well known in the art. However, it should be appreciated that certain aspect and advantages of the present invention can be achieved with buffering systems modified to receive other types of wafer carriers. For example, those of skill in the art will recognize that certain aspects of the arrangements described above can be modified to accept enclosed wafer carriers of various other shapes and sizes. Moreover, those of skill in the art will also recognize that certain aspects of the arrangements described above can be modified to accept open wafer cassettes. For example, the buffering system is preferably sealed in such arrangements so that the wafers are protected from dust and other contaminants.

It also should be noted that certain objects and advantages of the invention have been described above for the purpose of describing the invention and the advantages achieved over the prior art. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Moreover, although this invention has been disclosed in the context of certain preferred embodiments and examples, it will be understood by those skilled in the art that the present invention extends beyond the specifically disclosed embodiments to other alternative embodiments and/or uses of the invention and obvious modifications and equivalents thereof. In addition, while a number of variations of the invention have been shown and described in detail, other modifications, which are within the scope of this invention, will be readily apparent to those of skill in the art based upon this disclosure. For example, it is contemplated that various combination or subcombinations of the specific features and aspects of the embodiments may be made and still fall within the scope of the invention. Accordingly, it should be understood that various features and aspects of the disclosed embodiments can be combined with or substituted for one another in order to form varying modes of the disclosed invention. Thus, it is intended that the scope of the present invention herein disclosed should not be limited by the particular disclosed embodiments described above, but should be determined only by a fair reading of the claims that follow.

We claim:

1. A buffering system for use with a wafer processing system comprising:
a frame;
a first input/output (I/O) station for loading and unloading wafer carriers, each wafer carrier being configured for holding a plurality of wafers;
a wheel, the wheel including a plurality of shelves, each shelf configured for supporting one of the wafer carriers, the wheel being supported for rotation on the frame about a generally horizontal axis;
a drive mechanism that is configured to rotate the wheel about the generally horizontal axis; and
a wafer carrier port that is communication with a wafer handling chamber.

2. The buffering system of claim 1, further comprising a wafer carrier transfer mechanism that is configured to transfer the wafer carriers between the I/O station and the shelves.

3. The buffering system of claim 2, wherein the wafer carrier transfer mechanism comprises a shuttle that includes a support positioned on a horizontal track.

4. The buffering system as in claim 3, wherein the support can pivot about a vertical axis with respect to the wafer carrier port.

5. The buffering system of claim 3, wherein the wafer carrier transfer mechanism is also configured to transfer the wafer carriers between the shelves and the wafer carrier port.

6. The buffering system of claim 3, wherein the wafer carriers are transferred from the shelves by positioning the support under the shelves to interfere with the rotation of the wafer carrier on the wheel.

7. The buffering system of claim 3, wherein the wafer carriers are transferred to the shelves by positioning the support with a wafer carrier above a shelf to interfere with the rotation of the shelf on the wheel.

8. The buffering system of claim 1, wherein the wafer carriers provide a substantially closed environment for a plurality of wafers positioned within the wafer carrier.

9. The buffering system of claim 8, wherein the wafer carriers are standard front opening unified pods.

10. The buffering system of claim 1, wherein the wafer carriers are open and the frame defines a substantially closed environment.

11. The buffering system of claim 1, wherein each shelf is configured to rotate as the wheel rotates about the generally horizontal axis.

12. The buffering system of claim 1, wherein the wafer carriers hang from the shelves.

13. The buffering system of claim 1, further comprising a second I/O station for loading and unloading wafer carriers.

14. The buffering system of claim 1, wherein the first I/O station is configured to receive a wafer carrier from an overhead hoist transport system.

15. The buffering system of claim 1, wherein the first I/O station is configured to such that a wafer carrier can be loaded directly onto the shelves.

16. The buffering system of claim 1, further comprising a second wafer carrier port.

17. The buffering system of claim 16, wherein the second wafer carrier port is located generally above the first wafer carrier port.

18. The buffering system of claim 17, further comprising a first wafer carrier transfer mechanism that is configured to transfer the wafer carriers between the shelves and the first wafer carrier port and a second wafer carrier transfer mechanism that is configured to transfer the wafer carriers between the shelves and the second wafer carrier port.

19. The buffering system of claim 17, further comprising a wafer carrier transfer mechanism that includes an elevator and is configured to transfer the wafer carriers between the shelves and the first and second wafer carrier ports.

20. The buffering system of claim 1, further comprising a wafer handing chamber that is in communication with the wafer carrier port.

21. The buffering system of claim 20, wherein the wafer handling chamber includes a wafer handing robot that is configured to move wafers in and out of a wafer carrier through the wafer carrier port.

22. The buffering system of claim 20, wherein the wafer handling robot is also configured to move wafers in an out of a processing system that is also in communication with the wafer handling chamber.

23. The buffering system of claim 20, wherein at least a portion of the wafer handling chamber is positioned within the frame such that the shelves rotate around at least a portion of the wafer handling chamber.

24. A buffering system for use with a wafer processing system, comprising:
a frame located substantially above the wafer processing system;
an input/output (I/O) station for loading and unloading wafer carriers that are configured for holding a plurality of wafers;
a wheel, including a plurality of shelves for supporting the wafer carriers, the wheel being supported for rotation on said frame about a generally vertical axis; and
a drive mechanism that is configured to rotate the wheel about the generally vertical axis; and
a wafer carrier port that is communication with a wafer handling chamber.

25. The buffering system of claim 20, comprising a plurality of stacked wheels, each of the wheels including a plurality of shelves for supporting the wafer carriers.

26. A buffering system for use with a wafer processing system, comprising a frame and a wheel, said wheel supporting a plurality of wafer carriers, said wheel being supported by said frame for rotation about a generally horizontal axis.

27. The buffering system of claim 26, further including a first door for transporting said plurality of wafers into said buffering system, a second door located between said wafer buffering system and said processing system, and a shuttle for transporting wafers from said first door to said second door.

28. A buffering system for use with a wafer processing system, comprising a frame and a wheel, said wheel including plurality of positions for supporting a plurality of wafer carriers, said wheel being supported for rotation about a generally vertical axis and being located above the wafer processing system.

29. A method for providing wafers to a wafer processing system, comprising:
loading a wafer carrier onto an input/output (I/O) station of a buffering system;
transferring the wafer carrier to one of a plurality of shelves positioned on a wheel for rotation about a generally horizontal axis;
rotating the wafer carrier about the generally horizontal axis;
transferring the wafer carrier from the one of a plurality of shelves to a wafer carrier port;
removing a wafer through the wafer carrier port; and
transferring the wafer to a processing chamber.

30. The method of claim 29, wherein transferring the wafer carrier to one of the plurality of shelves comprises positioning a support of a shuttle under one of the shelves to interfere with the rotation of the one of the shelves about the generally horizontal axis.

31. The method as in claim 29, wherein transferring the wafer carrier from the one of a plurality of shelves comprises positioning a support of a shuttle above one of the shelves with the wafer carrier to interfere with the rotation of the shelf on the wheel.
